(19) United States
(12) Patent Application Publication
(10) Pub. No.: US 2026/0068567 A1
(43) Pub. Date: Mar. 5, 2026

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventors: Takayuki YAMAMOTO, Toyama (JP); Kaigo TAHARA, Toyama (JP); Hideki HORITA, Toyama (JP)

(73) Assignee: KOKUSAI ELECTRIC CORPORATION, Tokyo (JP)

(21) Appl. No.: 19/318,585

(22) Filed: Sep. 4, 2025

(30) Foreign Application Priority Data
Sep. 5, 2024 (JP) 2024-152865

(51) Int. Cl. H01L 21/311; H01L 21/67

(52) U.S. Cl. CPC H01L 21/31116

(57) ABSTRACT

There is provided a technique that includes: (a) establishing a state in which a product substrate and a non-product substrate to which a substance M is adsorbed are placed in a processing chamber; and (b) etching a surface of the product substrate by supplying an etching agent into the processing chamber in the state in which the product substrate and the non-product substrate are placed to cause the substance M adsorbed to the non-product substrate to react with the etching agent.

### CROSS-REFERENCE TO RELATED APPLICATION

This application is based upon and claims the benefit of priority from Japanese Patent Application No. 2024-152865, filed on Sep. 5, 2024, the entire contents of which are incorporated herein by reference.

### FIELD

The present disclosure relates to a processing method, a method of manufacturing a semiconductor device, a processing apparatus, and a recording medium.

### DESCRIPTION OF THE RELATED ART

As one of the steps of manufacturing a semiconductor device, processing of etching the surface of a substrate might be performed.

### SUMMARY

The present disclosure provides a technique that can efficiently perform etching of the surface of a substrate.

According to one embodiment of the present disclosure, provided is a technique including:
(a) establishing a state in which a product substrate and a non-product substrate to which a substance M is adsorbed are placed in a processing chamber; and
(b) etching a surface of the product substrate by supplying an etching agent into the processing chamber in the state in which the product substrate and the non-product substrate are placed to cause the substance M adsorbed to the non-product substrate to react with the etching agent.

### BRIEF DESCRIPTION OF THE DRAWINGS

FIG. 1 is a schematic configuration diagram of a vertical processing furnace in a processing apparatus suitably used in one embodiment of the present disclosure, illustrating a longitudinal sectional view of a processing furnace 202 portion.

FIG. 2 is a schematic configuration diagram of the vertical processing furnace in the processing apparatus suitably used in one embodiment of the present disclosure, illustrating a cross-sectional view of the processing furnace 202 portion taken along line A-A of FIG. 1.

FIG. 3 is a schematic configuration diagram of a controller 121 of the processing apparatus suitably used in one embodiment of the present disclosure, illustrating a control system of a controller 121 in a block diagram.

FIG. 4 is a diagram illustrating a process flow in one embodiment of the present disclosure.

FIG. 5A is a schematic diagram illustrating a state in a processing container after step A is performed, and FIG. 5B is a schematic diagram illustrating a state in the processing container after step A′ is performed.

FIG. 6 is a schematic cross-sectional view illustrating a surface portion of a substrate after a film is formed by performing a cycle including steps A to D a plurality of times.

FIG. 7 is a diagram illustrating a measurement result of an etching amount of a native oxide film on a surface of a substrate.

### DETAILED DESCRIPTION

### One Embodiment of Present Disclosure

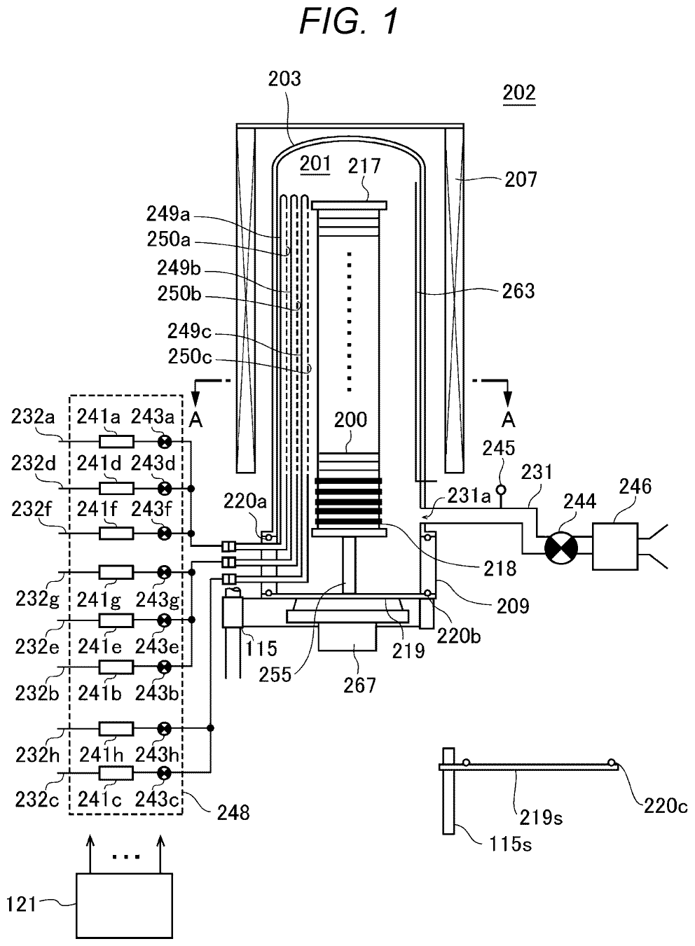

One embodiment of the present disclosure is hereinafter described mainly with reference to FIGS. 1 to 4, 5A, and 5B. Note that the drawings used in the following description are all schematic, and the dimensional relationship between elements, the ratio between elements, and the like illustrated in the drawings do not necessarily coincide with actual ones. Between a plurality of drawings, the dimensional relationship between the elements and the ratio between the elements do not necessarily coincide with each other.

### (1) Configuration of Processing Apparatus

As illustrated in FIG. 1, a processing furnace 202 of a processing apparatus includes a heater 207 as a temperature regulator (heater). The heater 207 has a cylindrical shape and is supported by a holding plate for vertical installation. The heater 207 also functions as an activator (exciter) that thermally activates (excites) a gas.

Inside the heater 207, a reaction tube 203 is arranged concentrically with the heater 207. The reaction tube 203 is formed of, for example, a heat-resistant material such as quartz (SiO₂) or silicon carbide (SiC), and is formed into a cylindrical shape with an upper end closed and a lower end opened. A manifold 209 is arranged below the reaction tube 203 concentrically with the reaction tube 203. The manifold 209 is formed of a metal material such as stainless steel (SUS), for example, into a cylindrical shape with an upper end and a lower end opened. An upper end portion of the manifold 209 engages with a lower end portion of the reaction tube 203 and is configured to support the reaction tube 203. An O-ring 220a as a seal member is provided between the manifold 209 and the reaction tube 203. The reaction tube 203 is vertically installed in a similar manner to the heater 207. A processing container (reaction container) is formed mainly of the reaction tube 203 and the manifold 209. A processing chamber 201 is formed in a hollow cylinder portion of the processing container. The processing chamber 201 is configured to be able to accommodate a wafer 200 as a product substrate. The wafer 200 is processed in the processing chamber 201.

In the processing chamber 201, nozzles 249a to 249c as first to third suppliers, respectively, are provided so as to penetrate a side wall of the manifold 209. The nozzles 249a to 249c are also referred to as first to third nozzles, respectively. The nozzles 249a to 249c are each formed of, for example, a heat-resistant material such as quartz or SiC. Gas supply pipes 232a to 232c are connected to the nozzles 249a to 249c, respectively. The nozzles 249a to 249c are nozzles different from one another, and the nozzles 249a and 249c are provided adjacent to the nozzle 249b.

The gas supply pipes 232a to 232c are provided with mass flow controllers (MFCs) 241a to 241c as flow rate controllers (flow rate controllers), and valves 243a to 243c as opening/closing valves, respectively, in this order from an upstream side of a gas flow. Gas supply pipes 232d and 232f are connected to the gas supply pipe 232a on the downstream side of the valve 243a. Gas supply pipes 232e and 232g are connected to the gas supply pipe 232b on the downstream side of the valve 243b. A gas supply pipe 232h is connected to the gas supply pipe 232c on a downstream side of the valve 243c. The gas supply pipes 232d to 232h are provided with MFCs 241d to 241h and valves 243d to 243h, respectively, in this order from the upstream side of the gas flow. The gas supply pipes 232a to 232h are each formed of, for example, a metal material such as SUS.

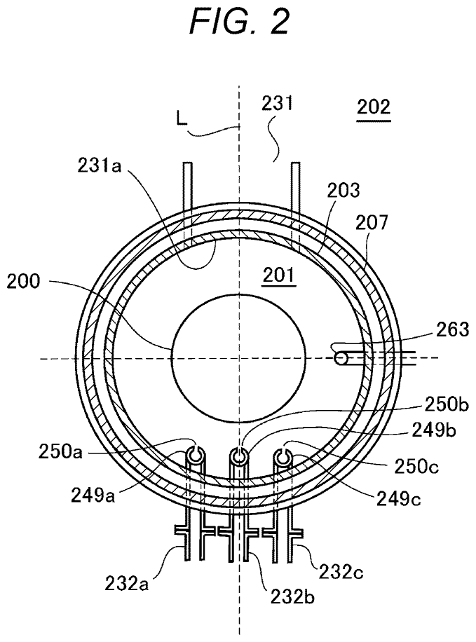

As illustrated in FIG. 2, the nozzles 249a to 249c are provided in an annular space in a plan view between an inner wall of the reaction tube 203 and the wafer 200 so as to extend upward in an arrangement direction of the wafers 200 along the inner wall of the reaction tube 203 from a lower portion to an upper portion. That is, the nozzles 249a to 249c are provided along a wafer arrangement region, in a region horizontally surrounding the wafer arrangement region on a lateral side of the wafer arrangement region in which the wafers 200 are arranged. In a plan view, the nozzle 249b is arranged so as to be opposed to an exhaust port 231a to be described later on a straight line across the center of the wafer 200 in the processing chamber 201. The nozzles 249a and 249c are arranged so as to interpose a straight line L passing through the nozzle 249b and the center of the exhaust port 231a from both sides along the inner wall of the reaction tube 203 (outer peripheral portion of the wafer 200). The straight line L also passes through the nozzle 249b and the center of the wafer 200. That is, it can also be said that the nozzle 249c is provided on a side opposite to the nozzle 249a across the straight line L. The nozzles 249a and 249c are arranged in line symmetry with the straight line L as a symmetry axis. On side surfaces of the nozzles 249a to 249c, gas supply holes 250a to 250c through which a gas is supplied are formed, respectively. The gas supply holes 250a to 250c are each opened so as to be opposed to (face) the exhaust port 231a in a plan view, and can supply the gas toward the wafer 200. A plurality of gas supply holes 250a to 250c is formed from the lower portion to the upper portion of the reaction tube 203.

A fluorine (F)-containing substance is supplied from the gas supply pipe 232a into the processing chamber 201 via the MFC 241a, the valve 243a, and the nozzle 249a. The F-containing substance is used as one of the etching agents.

A source is supplied from the gas supply pipe 232b into the processing chamber 201 via the MFC 241b, the valve 243b, and the nozzle 249b. The source is used as one of the film-forming agents.

A dopant is supplied from the gas supply pipe 232c into the processing chamber 201 via the MFC 241c, the valve 243c, and the nozzle 249c. The dopant is used as one of the film-forming agents.

A reducing agent is supplied from the gas supply pipe 232d into the processing chamber 201 via the MFC 241d, the valve 243d, the gas supply pipe 232a, and the nozzle 249a.

Another source is supplied from the gas supply pipe 232e into the processing chamber 201 via the MFC 241e, the valve 243e, the gas supply pipe 232b, and the nozzle 249b. Another source is used as one of the film-forming agents.

An inert gas is supplied from the gas supply pipes 232f to 232h into the processing chamber 201 via the MFCs 241f to 241h, the valves 243f to 243h, the gas supply pipes 232a to 232c, and the nozzles 249a to 249c, respectively. The inert gas acts as a purge gas, a carrier gas, a diluent gas and the like.

An F-containing substance supply system is mainly formed of the gas supply pipe 232a, the MFC 241a, and the valve 243a. A source supply system is mainly formed of the gas supply pipe 232b, the MFC 241b, and the valve 243b. A dopant supply system is mainly formed of the gas supply pipe 232c, the MFC 241c, and the valve 243c. A reducing agent supply system is mainly formed of the gas supply pipe 232d, the MFC 241d, and the valve 243d. Another source supply system is mainly formed of the gas supply pipe 232e, the MFC 241e, and the valve 243e. An inert gas supply system is mainly formed of the gas supply pipes 232f to 232h, the MFCs 241f to 241h, and the valves 243f to 243h. The fluorine-containing substance supply system is also referred to as an etching agent supply system. Each or all of the source supply system, the dopant supply system, and another source supply system is also referred to as a film-forming agent supply system.

Any one or all of the various supply systems described above may be formed as an integrated supply system 248 in which the valves 243a to 243h, the MFCs 241a to 241h, and the like are integrated. The integrated supply system 248 is connected to each of the gas supply pipes 232a to 232h, and is configured such that a supplying operation of various substances (various gases) into the gas supply pipes 232a to 232h, that is, an opening/closing operation of the valves 243a to 243h, a flow rate regulating operation by the MFCs 241a to 241h and the like is controlled by a controller 121 to be described later. The integrated supply system 248 is formed as an integral or separable integrated unit, can be attached to or detached from the gas supply pipes 232a to 232h and the like on an integrated unit basis, and is configured to be capable of maintaining, replacing, adding, and the like the integrated supply system 248 on an integrated unit basis.

The exhaust port 231a from which an atmosphere inside the processing chamber 201 is discharged is formed below a side wall of the reaction tube 203. As illustrated in FIG. 2, the exhaust port 231a is provided at a position opposed to (facing) the nozzles 249a to 249c (gas supply holes 250a to 250c) across the wafer 200 in a plan view. The exhaust port 231a may be provided along the side wall of the reaction tube 203 from the lower portion toward the upper portion, that is, along the wafer arrangement region. An exhaust pipe 231 is connected to the exhaust port 231a. A vacuum pump 246 serving as a vacuum exhauster is connected to the exhaust pipe 231 via a pressure sensor 245 serving as a pressure detector (pressure detector) that detects a pressure in the processing chamber 201 and an auto pressure controller (APC) valve 244 serving as a pressure regulator (pressure regulator). The APC valve 244 is configured to be capable of performing vacuum exhaust and stop the vacuum exhaust inside the processing chamber 201 by opening and closing the valve in a state in which the vacuum pump 246 is operated, and to be capable of further regulating the pressure in the processing chamber 201 by regulating a degree of valve opening on the basis of pressure information detected by the pressure sensor 245 in a state in which the vacuum pump 246 is operated. An exhaust system is formed mainly of the exhaust pipe 231, the APC valve 244, and the pressure sensor 245. The vacuum pump 246 may be included in the exhaust system.

A seal cap 219 as a furnace opening lid capable of hermetically closing the lower end opening of the manifold 209 is provided below the manifold 209. The seal cap 219 is formed of, for example, a metal material such as SUS into a disk shape. An O-ring 220b as a seal member that abuts the lower end of the manifold 209 is provided on an upper surface of the seal cap 219. A rotator 267 that rotates a boat 217 to be described later is arranged below the seal cap 219. A rotating shaft 255 of the rotator 267 penetrates the seal cap 219 and is connected to the boat 217. The rotator 267 is configured to rotate the boat 217, thereby rotating the wafer 200. A boat elevator 115 as a lifter provided outside the reaction tube 203 is configured to vertically lift the seal cap 219. The boat elevator 115 is configured as a transferer that lifts the seal cap 219, thereby carrying (transferring) the wafer 200 into/out of the processing chamber 201, and functions as an apparatus (preparation apparatus) that arranges the product substrate and a non-product substrate to which a substance M is adsorbed in the processing container.

Below the manifold 209, a shutter 219s serves as a furnace opening lid capable of hermetically closing the lower end opening of the manifold 209 in a state in which the seal cap 219 is lowered and the boat 217 is carried out of the processing chamber 201. The shutter 219s is formed of, for example, a metal material such as SUS into a disk shape. An O-ring 220c as a seal member that abuts the lower end of the manifold 209 is provided on an upper surface of the shutter 219s. An opening/closing operation (lifting operation, rotating operation, and the like) of the shutter 219s is controlled by a shutter opener/closer 115s.

The boat 217 as a support is configured to support a plurality of, for example, 25 to 200 wafers 200 horizontally, in multiple stages, so as to be aligned vertically with the centers aligned with one another, that is, to arrange at intervals. The boat 217 is configured to be capable of supporting a predetermined number (one or more) of non-product wafers as non-product substrates or dummy wafers as dummy substrates in multiple stages, similarly to the wafers 200 as the product substrates. Note that the boat 217 is configured to be capable of supporting a side dummy wafer and a fill dummy wafer in addition to them. The boat 217 is formed of, for example, a heat-resistant material such as quartz and SiC. Heat insulating plates 218, each formed of a heat-resistant material such as quartz and SiC, for example, are supported in multiple stages in a lower portion of the boat 217. The boat 217 can also be considered as a part of the preparation apparatus described above.

A temperature sensor 263 serving as a temperature detector is provided in the reaction tube 203. By regulating a degree of energization to the heater 207 on the basis of temperature information detected by the temperature sensor 263, a desired temperature distribution can be achieved in the processing chamber 201. The temperature sensor 263 is provided along the inner wall of the reaction tube 203.

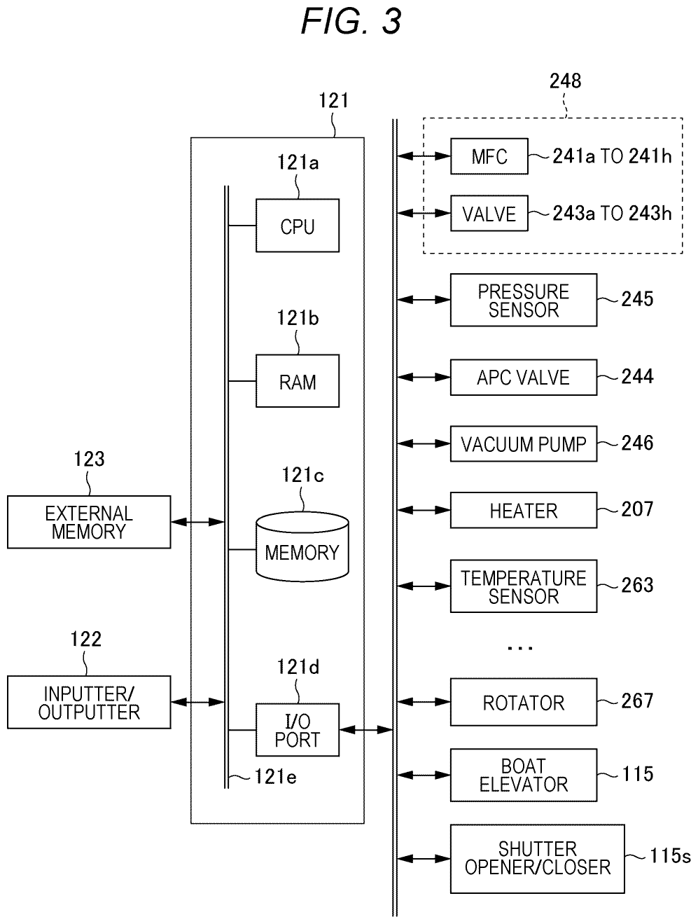

As illustrated in FIG. 3, a controller 121 as a controller (control means) is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output 122 configured as, for example, a touch panel and the like is connected to the controller 121. An external memory 123 can be connected to the controller 121. Note that, the processing apparatus may be provided with one controller or a plurality of controllers. That is, control for performing a processing sequence to be described later may be performed using one controller or a plurality of controllers. A plurality of controllers may be configured as a control system mutually connected by a wired or wireless communication network, and control for performing the processing sequence to be described later may be performed by an entire control system. In a case where the term “controller” is used in the present specification, there is a case where a plurality of controllers is included and a case where a control system formed of a plurality of controllers is included in addition to a case where one controller is included.

The memory 121c is formed of, for example, a flash memory, a hard disk drive (HDD), a solid state drive (SSD) and the like. In the memory 121c, a control program that controls an operation of the processing apparatus, a process recipe in which procedures, conditions and the like of substrate processing to be described later are described and the like are readably recorded and stored. The process recipe is a combination formed such that the controller 121 causes the processing apparatus to execute each procedure in substrate processing to be described later to obtain a predetermined result, and functions as a program. Hereinafter, the process recipe, the control program and the like are collectively and simply referred to as a program (program product). The process recipe is simply referred to as a recipe. In a case where the term “program” is used in the present specification, there is a case where the recipe alone is included, a case where the control program alone is included, or a case where both of them are included. The RAM 121b is configured as a memory area (work area) in which programs, data, and the like read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opener/closer 115s and the like described above.

The CPU 121a is configured to be capable of reading the control program from the memory 121c and executing the same, and reading the recipe from the memory 121c in response to an input and the like of an operation command from the input/output 122. The CPU 121a is configured to be capable of controlling, in accordance with a content of the read recipe, a flow rate regulating operation of various substances (various gases) by the MFCs 241a to 241h, an opening/closing operation of the valves 243a to 243h, a pressure regulating operation by the APC valve 244 based on an opening/closing operation of the APC valve 244 and the pressure sensor 245, start and stop of the vacuum pump 246, a temperature regulating operation of the heater 207 based on the temperature sensor 263, rotation and rotating speed regulating operation of the boat 217 by the rotator 267, a lifting operation of the boat 217 by the boat elevator 115, an opening/closing operation of the shutter 219s by the shutter opener/closer 115s and the like.

The controller 121 can be configured by installing the above-described program recorded and stored in the external memory 123 into the computer. Examples of the external memory 123 include, for example, a magnetic disk such as an HDD, an optical disk such as a CD, a semiconductor memory such as a USB memory, an SSD and the like. The memory 121c and the external memory 123 are configured as computer-readable recording media. Hereinafter, they are collectively and simply referred to as recording media. In a case where the term “recording medium” is used in the present specification, there is a case where only the memory 121c is included, a case where only the external memory 123 is included, or a case where both of them are included. Note that, the program may be provided to the computer by using a communication means such as the Internet and a dedicated line without using the external memory 123.

### (2) Processing Step

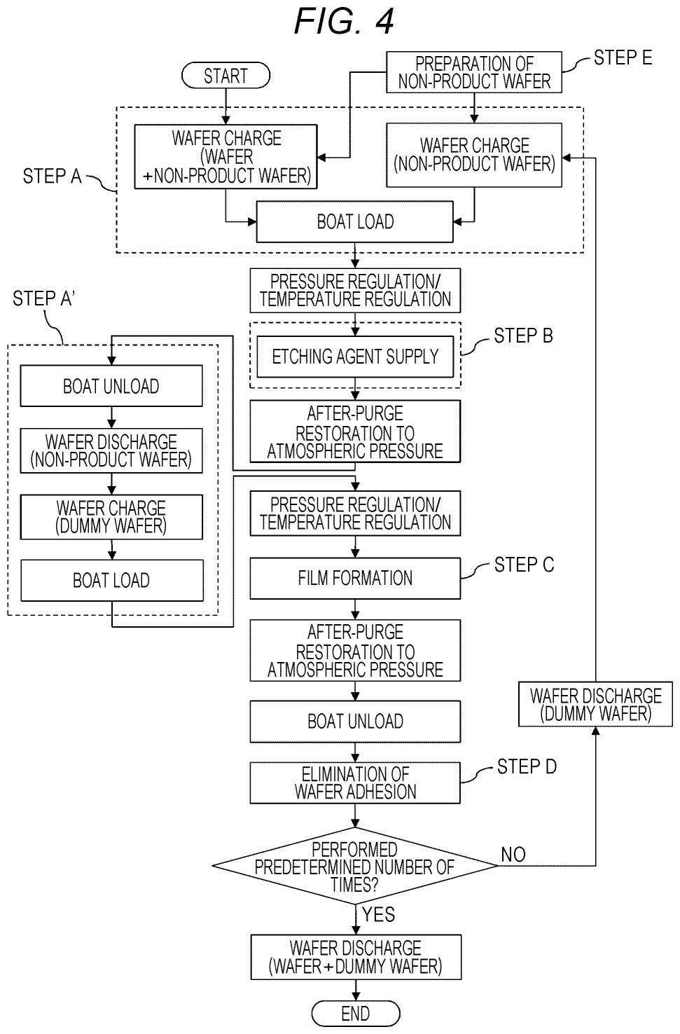

As one step of steps of manufacturing (a method of manufacturing) a semiconductor device using the processing apparatus described above, an example of a method of processing a substrate (processing method), that is, an example of a processing sequence in which a processing sequence for etching a surface of the wafer 200 as the product substrate and a processing sequence for causing a film to grow on the wafer 200 after the etching are successively performed a predetermined number of times is described mainly with reference to FIG. 4. In the following description, the controller 121 controls the operation of each unit forming the processing apparatus. Note that, the processing apparatus is also referred to as a substrate processing apparatus, an etching processing apparatus, an etching apparatus, a film-forming processing apparatus, or a film-forming apparatus according to each processing content. Note that, the processing method is also referred to as a substrate processing method, an etching processing method, an etching method, a film-forming processing method, or a film-forming method according to each processing content.

In the processing sequence according to the present embodiment,
(a) step A of establishing a state in which the wafer 200 as the product substrate and the non-product wafer as the non-product substrate to which the substance M is adsorbed are placed in the processing chamber 201, and
(b) step B of etching the surface of the wafer 200 by supplying the etching agent into the processing chamber 201 in the state in which the wafer 200 and the non-product wafer to which the substance M is adsorbed are placed, thereby causing the substance M adsorbed to the non-product wafer and the etching agent to react with each other are performed.

Note that, in the following example, a case of performing
(c) step C of forming the film on the wafer 200 by supplying the film-forming agent to the wafer 200 the surface of which is etched, and
performing a cycle including steps A, B, and C a predetermined number of times (n times, n is 1 or an integer not smaller than 2) is described.

In the following example,
a case of performing step C in the processing chamber 201 in a state in which the non-product wafer to which the substance M is adsorbed is removed is described.

In the following example,
a case of performing step B in a state in which the wafer 200 and the non-product wafer to which the substance M is adsorbed are supported by the boat 217 as the support in the processing chamber 201, and performing step C in a state in which the wafer 200 is supported by the boat 217 in the processing chamber 201 is described.

In the following example, a case of further performing
(a′) step A′ of carrying the boat 217 in a state of supporting the wafer 200 into the processing chamber 201 after carrying the boat 217 out of the processing chamber 201 and removing the non-product wafer to which the substance M is adsorbed from the boat 217 outside the processing chamber 201 after performing step B and before performing step C in the above-described cycle is described.

Note that, in the following example,
a case of charging the dummy wafer as the dummy substrate at a site where the non-product wafer to which the substance M is adsorbed is removed in the boat 217, and carrying the boat 217 that supports the wafer 200 and the dummy wafer into the processing chamber 201 at step A′ is described.

In the following example, a case of further performing
(d) step D of carrying the boat 217 out of the processing chamber 201 and separating the wafer 200 from the boat 217 outside the processing chamber 201, thereby eliminating adhesion of the wafer 200 to the boat 217 by the film after performing step C in the above-described cycle is described.

In the following example, a case of further performing
(e) step E of preparing the non-product wafer to which the substance M is adsorbed outside the processing chamber 201, and
performing at least any one of steps A, B, C, and D in an m-th cycle (m is an integer not smaller than 1) and step E in an (m+1)-th cycle in parallel is described.

The term “wafer” used in the present specification might mean the wafer itself, or a laminate of the wafer and a predetermined layer or film formed on the surface thereof. The term “surface of the wafer” used in the present specification might mean the surface of the wafer itself or a surface of a predetermined film and the like formed on the wafer. In a case where it is described as “forming a predetermined film on the surface of the wafer” in the present specification, this might mean that a predetermined film is directly formed on the surface of the wafer itself or that a predetermined film is formed on the film and the like formed on the wafer. In a case where the term “substrate” is used in the present specification, this is a synonym of the term “wafer”.

The term “agent” and “substance” used in the present specification include at least either of a gaseous substance or a liquid substance. The liquid substance includes a mist substance. That is, each of the etching agent, the reducing agent, and the film-forming agent (source, dopant and the like) may include the gaseous substance, the liquid substance such as the mist substance, or both of them.

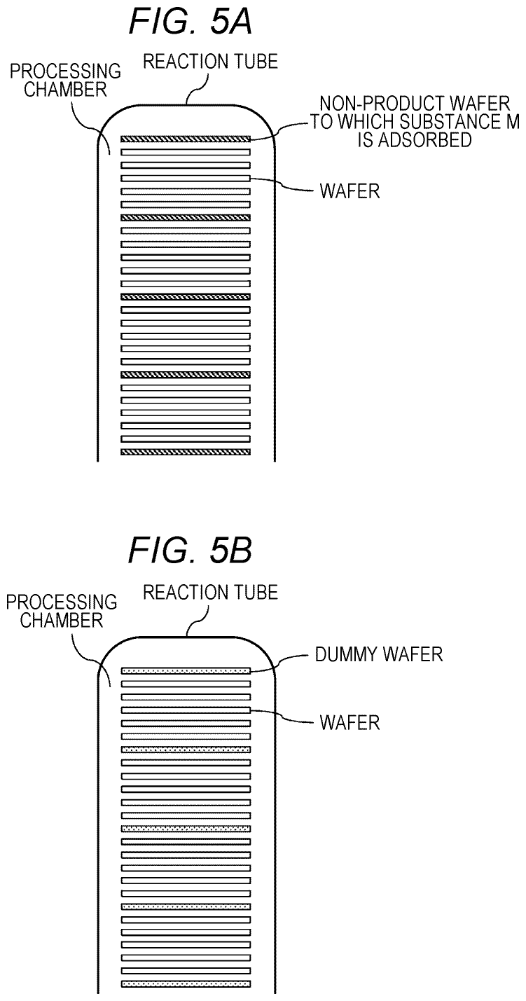

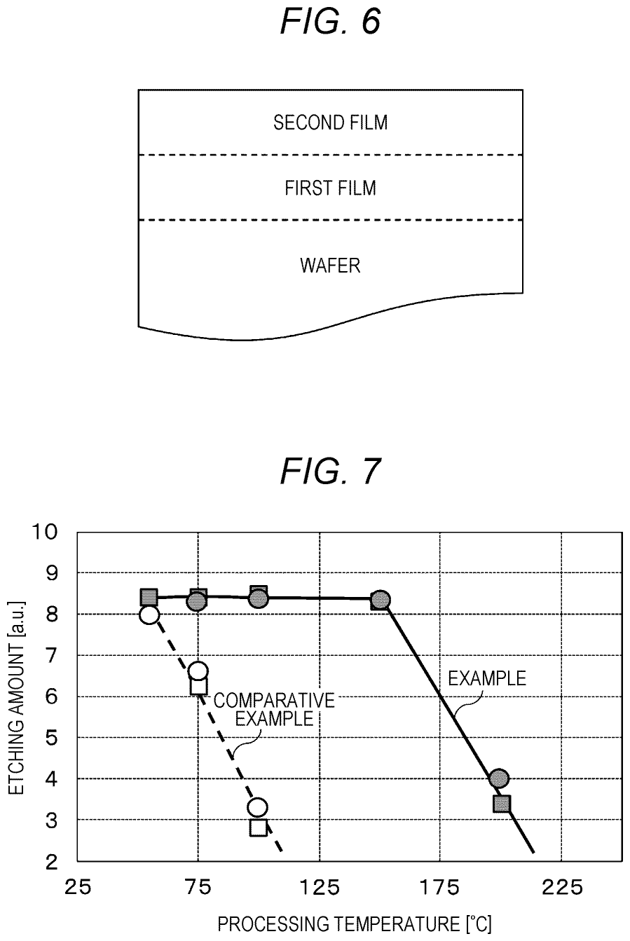

In the present specification and the drawings, the product substrate (product wafer) is also simply referred to as the wafer or the wafer 200 for convenience. In the present specification and the drawings, the non-product substrate to which the substance M is adsorbed (non-product wafer to which the substance M is adsorbed) is also simply referred to as the non-product substrate (non-product wafer) for convenience. For example, in FIG. 4, for convenience, the product wafer is simply referred to as the wafer, and the non-product wafer to which the substance M is adsorbed is simply referred to as the non-product wafer. In FIGS. 5A, 5B, and 6, the product wafer is simply referred to as the wafer for convenience.

### (Step A)

First, a plurality of wafers 200 as the product substrates and the non-product wafer as the non-product substrate to which the substance M is adsorbed are charged on the boat 217 (wafer charge).

There is a case where an oxide is formed on the surface of the wafer 200. There is a case where the oxide includes at least either of a silicon oxide film having a non-stoichiometric composition (SiOₓ film, x is a real number smaller than 2) or a silicon oxide film having a stoichiometric composition (SiO₂ film). There is a case where the oxide includes at least one of a native oxide film or a chemical oxide film. Note that the SiOₓ film and the SiO₂ film are hereinafter also collectively referred to as Sio films.

As the substance M to be adsorbed to the non-product wafer, an oxygen (O)- and hydrogen (H)-containing substance can be used, and for example, a substance containing a hydroxy group (OH group) can be used. As the substance M, for example, water (H₂O), alcohol (R—OH, R is a hydrocarbon), hydrogen peroxide (H₂O₂) and the like can be used. One or more of them can be used as the substance M. Note that, in order to suppress volatilization from the non-product wafer, it is preferable to use a substance having a hydrogen bond, such as H₂O, as the substance M.

The non-product wafer to which the substance M is adsorbed can be prepared (manufactured) by exposing a substrate such as a silicon (Si) wafer as the non-product wafer to the substance M such as the above-described O- and H-containing substances outside the processing chamber 201. For example, the non-product wafer to which the substance M is adsorbed can be prepared by, when checking the number, a state and the like of the non-product wafers stored inside a substrate storing container (FOUP), opening a lid of the container, introducing the atmosphere into the container, and exposing the non-product wafer to the atmosphere. In this case, the substance M to be adsorbed to the non-product wafer includes moisture (H₂O) in the atmosphere.

In the boat 217, the non-product wafer to which the substance M is adsorbed can be arranged every other wafer 200 or every plural wafers 200, that is, every other product substrate or every plural product substrates. The number of the non-product wafers to which the substance M is adsorbed, charged on the boat 217, can be made equal to or smaller than the number of the wafers 200 charged on the boat 217, or can be made smaller than the number of the wafers 200 charged on the boat 217. In the boat 217, a plurality of wafers 200 and a plurality of non-product wafers to which the substance M is adsorbed can be arranged.

After the wafer charge is finished, the shutter 219s is moved by the shutter opener/closer 115s, so that the lower end opening of the manifold 209 is opened (shutter open). Thereafter, as illustrated in FIG. 1, the boat 217 that supports the wafer 200 and the non-product wafer to which the substance M is adsorbed is raised by the boat elevator 115 and is carried into the processing chamber 201 (boat load). In this state, the lower end of the manifold 209 is sealed with the seal cap 219 via the O-ring 220b.

By completion of the boat load, as illustrated in FIG. 5A, the wafer 200 as the product substrate and the non-product wafer as the non-product substrate to which the substance M is adsorbed are arranged in the processing chamber 201. FIG. 5A illustrates a case where the non-product wafer to which the substance M is adsorbed is arranged in a plurality of wafers, that is, a plurality of product substrates. To put it more specifically, FIG. 5A illustrates a case where the non-product wafer to which the substance M is adsorbed is arranged every plural wafers, that is, every plural product substrates. The non-product wafer to which the substance M is adsorbed is arranged at a position away from the wafer and adjacent to the wafer.

### (Pressure Regulation and Temperature Regulation)

After the boat load is finished, the inside of the processing chamber 201, that is, a space in which the wafer 200 and the non-product wafer to which the substance M is adsorbed are present, is vacuum-exhausted (decompression-exhausted) by the vacuum pump 246 so as to achieve a desired pressure (vacuum degree). At that time, the pressure in the processing chamber 201 is measured by the pressure sensor 245, and the APC valve 244 is feedback-controlled on the basis of measured pressure information. The heater 207 heats such that the wafer 200 and the non-product wafer in the processing chamber 201 reach the desired processing temperature. At that time, on the basis of the temperature information detected by the temperature sensor 263, the degree of energization to the heater 207 is feedback-controlled in such a manner that the desired temperature distribution is obtained in the processing chamber 201. The rotator 267 starts rotating the wafer 200 and the non-product wafer. Both the exhaust in the processing chamber 201 and the heating and rotation of the wafer 200, and the non-product wafer continue at least until the processing on the wafer 200 is finished.

### (Step B)

Thereafter, the etching agent is supplied into the processing chamber 201 in a state in which the wafer 200 and the non-product wafer to which the substance M is adsorbed are arranged.

Specifically, the valve 243a is opened to cause the etching agent to flow into the gas supply pipe 232a. The etching agent, a flow rate of which is regulated by the MFC 241a, is supplied into the processing chamber 201 via the nozzle 249a and discharged from the exhaust port 231a. At that time, the etching agent is supplied to the wafer 200 and the non-product wafer from the lateral side of the wafer 200 and the non-product wafer, and the wafer 200 and the non-product wafer are exposed to the etching agent (etching agent supply, exposure). At that time, the valves 243f to 243h may be opened to supply the inert gas into the processing chamber 201 via the nozzles 249a to 249c, respectively.

By supplying the etching agent into the processing chamber 201 in a state in which the wafer 200 and the non-product wafer to which the substance M is adsorbed are arranged under processing conditions to be described later, the substance M adsorbed to the non-product wafer and the etching agent are caused to react with each other, and the surface of the wafer 200, that is, the oxide on the surface of the wafer 200 can be etched using a reaction product obtained by this reaction.

For example, in a case where the oxide on the surface of the wafer 200 includes silicon oxide (SiO₂), the substance M adsorbed to the non-product wafer includes water (H₂O), and the etching agent supplied into the processing chamber 201 includes hydrogen fluoride (HF), the reaction represented by the following formula can be caused to proceed under the conditions to be described later. That is, the oxide (SiO₂) on the surface of the wafer 200 can be etched using the reaction product (HF₂— and the like) obtained by the reaction between the substance M (H₂O) and the etching agent (HF).

2HF+H₂O—HF₂⁻+H₃O+

SiO₂+2HF₂⁻+2H₃O⁺>SiF₄+4H₂O

As described above, according to the present disclosure, the etching of the oxide (SiO₂) on the surface of the wafer 200 can be started by using the reaction between the etching agent (HF) and the substance M (H₂O) adsorbed to the non-product wafer as a trigger. When the etching of the oxide is started, the substance M adsorbed to the non-product wafer is consumed. However, in this reaction system, since moisture (H₂O) is generated by the etching of the oxide, the above-described reaction can be repeatedly caused to occur in a chain reaction without additionally supplying the substance M into the processing chamber 201, and the oxide on the surface of the wafer 200 can be etched. Note that, in this reaction system, in a case where the substance M is additionally supplied into the processing chamber 201, the amount of the substance M in this reaction system is excessive, and the progress of the etching reaction might be rather hindered.

After etching the surface of the wafer 200, the valve 243a is closed, and the supply of the etching agent into the processing chamber 201 is stopped. The inside of the processing chamber 201 is vacuum-exhausted to remove the gaseous substance and the like remaining in the processing chamber 201 from the inside of the processing chamber 201. At that time, the valves 243f to 243h are opened to supply the inert gas into the processing chamber 201 via the nozzles 249a to 249c, respectively. The inert gas supplied via the nozzles 249a to 249c acts as the purge gas, and the inside of the processing chamber 201 is purged by this (purge). Note that, the processing temperature when performing the purge at this step is preferably similar to the processing temperature when supplying the etching agent.

At that time, the valve 243d may be opened to supply the reducing agent into the processing chamber 201 instead of or together with the inert gas. At that time, cycle purge may be performed using the inert gas and/or reducing agent. In a case where the cycle purge is performed, the purge of the inside of the processing chamber 201 by the supply of at least either of the inert gas or the reducing agent into the processing chamber 201 and the exhaust (vacuum-exhaust) of the inside of the processing chamber 201 may be alternately performed a predetermined number of times, preferably a plurality of times. In this case, the supply of the reducing agent into the processing chamber 201 and the supply of the inert gas into the processing chamber 201 may be alternately performed a predetermined number of times, preferably a plurality of times in a state in which the inside of the processing chamber 201 is exhausted. In this case, in a state in which one of the inert gas and the reducing agent is continuously supplied into the processing chamber 201, the supply of the other of the inert gas and the reducing agent into the processing chamber 201 and the exhaust in the processing chamber 201 may be alternately performed a predetermined number of times, preferably a plurality of times. As a result, the substance remaining in the processing chamber can be efficiently and effectively discharged and removed from the processing chamber 201. Note that, in a case where the inert gas is used as the purge gas, the inside of the processing chamber 201 is purged mainly by a physical action. In contrast, in a case where the reducing agent is used as the purge gas, not only the physical action but also a chemical action can be generated, and a purge effect can be further enhanced. Note that, when the cycle purge is performed, opening/closing control of the valves 243f to 243h, the valve 243d, and the like is appropriately performed in accordance with a supply timing of the inert gas and the reducing agent.

Processing conditions when supplying the etching agent at step B are exemplified as follows:
processing temperature: room temperature (25° C.) to 170° C., preferably 25 to 150° C., more preferably 25 to 130° C.,
processing pressure: 10 to 4,000 Pa, preferably 500 to 2,000 Pa,
processing time: 1 to 120 minutes, preferably 10 to 100 minutes,
etching agent supply flow rate: 0.5 to 3 slm, preferably 1 to 2 slm, and
inert gas supply flow rate (per gas supply pipe): 0 to 10 slm, preferably 1 to 5 slm.

Note that, in the present specification, the expression of a numerical value range such as “25 to 170° C.” means that a lower limit value and an upper limit value are included in the range. Therefore, for example, “25 to 170° C.” means “equal to or higher than 25° C. and equal to or lower than 170° C.”. The same applies to other numerical value ranges. In the present specification, the processing temperature means the temperature of the wafer 200 or the temperature in the processing chamber 201, and the processing pressure means the pressure in the processing chamber 201. The processing time means the time during which the processing is continued. In a case where 0 (zero) slm is included in the supply flow rate, 0 (zero) slm means a case where the substance (gas) is not supplied. The same applies to the following description.

Here, if the processing temperature when supplying the etching agent at step B is set lower than the room temperature (25° C.), an etching rate can be increased, but in a case where another processing such as film-forming processing is performed at least either before or after the etching processing, a time (heatup time and/or cooldown time) for changing the processing temperature between the etching processing and another processing might become too long, and productivity might be lowered.

By setting the above-described processing temperature to the room temperature (25° C.) or higher, it is possible to shorten the change time of the processing temperature between this processing and another processing while maintaining the high etching rate, and it is possible to suppress the reduction in productivity.

When the above-described processing temperature is set to a temperature higher than 170° C., the change time of the processing temperature between this processing and another processing can be significantly shortened, but the etching rate might be excessively lowered, leading to a reduction in productivity.

By setting the above-described processing temperature to 170° C. or lower, it is possible to suppress the reduction in etching rate while maintaining a significant reduction in change time of the processing temperature between this processing and another processing, and it is possible to suppress the reduction in productivity. By setting the processing temperature to 150° C. or lower, it is possible to further suppress the reduction in etching rate while maintaining a significant reduction in change time of the processing temperature between this processing and another processing, and it is possible to further suppress the reduction in productivity. By setting the processing temperature to 130° C. or lower, it is possible to significantly suppress the reduction in etching rate while maintaining a significant reduction in change time of the processing temperature between this processing and another processing, and it is possible to significantly suppress the reduction in productivity.

From above, the above-described processing temperature is desirably set to the room temperature (25° C.) or higher and 170° C. or lower, preferably 25° C. or higher and 150° C. or lower, and more preferably 25° C. or higher and 130° C. or lower.

As the etching agent, as described above, the F-containing substance can be used, and for example, the F-containing substance containing hydrogen (H), such as hydrogen fluoride (HF) can be used. As the etching agent, for example, it is possible to use fluorine (F₂), nitrogen trifluoride (NF₃), chlorine trifluoride (ClF₃), chlorine fluoride (CIF), and the like. One or more of them can be used as the etching agent.

As the inert gas, a nitrogen (N₂) gas, or a rare gas such as an argon (Ar) gas, a helium (He) gas, a neon (Ne) gas, or a xenon (Xe) gas can be used. One or more of them can be used as the inert gas. The same applies to each step to be described later.

For example, the H-containing substance and a heavy hydrogen (D)-containing substance, such as hydrogen (H₂) and heavy hydrogen (D₂) and the like can be used as the reducing agent. One or more of them can be used as the reducing agent.

### (After-Purge and Atmospheric Pressure Restoration)

After step B is finished, the inert gas as the purge gas is supplied from each of the nozzles 249a to 249c into the processing chamber 201 and is discharged from the exhaust port 231a. As a result, the inside of the processing chamber 201 is purged, and a gas, a reaction by-product remaining in the processing chamber 201, and the like are removed from the inside of the processing chamber 201 (after-purge). Thereafter, the atmosphere in the processing chamber 201 is replaced with the inert gas (inert gas replacement), and the pressure in the processing chamber 201 is restored to a normal pressure (atmospheric pressure restoration).

### (Step A′)

After that, the boat elevator 115 lowers the seal cap 219, and the lower end of the manifold 209 is opened. Then, the processed wafer 200 and the non-product wafer are carried out of the reaction tube 203 from the lower end of the manifold 209 in a state of being supported by the boat 217 (boat unload). After the boat is unloaded, the shutter 219s is moved, and the lower end opening of the manifold 209 is sealed with the shutter 219s via the O-ring 220c (shutter close).

After the boat is unloaded, outside the processing chamber 201, the non-product wafer is taken out from the boat 217 (wafer discharge). Thereafter, the dummy wafer, as the dummy substrate is charged at a site where the non-product wafer is removed in the boat 217, that is, at a lacking site (wafer charge).

After the charge of the dummy wafer is finished, the shutter is opened and the boat load is performed by the processing procedure similar to that of the shutter open and the boat load at step A. By completion of the boat load, as illustrated in FIG. 5B, the wafer 200 as the product substrate and the dummy wafer as the dummy substrate are arranged in the processing chamber 201. FIG. 5B illustrates a case where the dummy wafer is arranged every plural wafers, that is, every plural product substrates.

Note that, when step A′ is performed, the etched wafer 200 might be exposed to the atmosphere in some cases. However, even in this case, the surface of the wafer 200 is in a state of being hardly oxidized, and the wafer 200 in is an atmosphere (environment) not easily oxidized. That is, the surface of the wafer 200 after performing step B is in a state of being terminated with hydrogen (H), and the temperature of the wafer 200 at the time of boat unload is a temperature equal to or lower than the processing temperature (room temperature to 170° C.) at step B and is relatively low. Therefore, the H termination is hardly detached from the surface of the wafer 200, and dangling bond is hardly generated on the surface of the wafer 200. Even when the wafer 200 is exposed to the atmosphere in this state, the surface of the wafer 200 is protected by the H termination, and a state of being hardly oxidized is maintained. Even if the surface of the wafer 200 is oxidized by performing step A′, the degree thereof is very small. Therefore, as described later, by performing a baking treatment and the like in a reducing agent atmosphere as necessary before starting step C, a slight amount of oxide generated on the surface of the wafer 200 can be removed by the reaction with the reducing agent.

### (Pressure Regulation and Temperature Regulation)

After step A′ is finished, the inside of the processing chamber 201 is vacuum-exhausted by the vacuum pump 246 so as to have a predetermined processing pressure at step C to be described later. An output of the heater 207 is regulated so that the temperature of the wafer 200 and that of the dummy wafer become the predetermined processing temperature to be described later.

Note that, as described above, before step C is started, the baking treatment may be performed in the reducing agent atmosphere as necessary. Specifically, the output of the heater 207 is regulated so that the temperature of each of the wafer 200 and the dummy wafer becomes the processing temperature of the baking treatment. Then, the valve 243d is opened to cause the reducing agent to flow into the gas supply pipe 232d. The reducing agent, the flow rate of which is regulated by the MFC 241d is supplied into the processing chamber 201 via the gas supply pipe 232a and the nozzle 249a, and discharged from the exhaust port 231a. At that time, the reducing agent is supplied from the lateral side of the wafer 200 to the wafer 200 and the dummy wafer, and the wafer 200 and the dummy wafer are exposed to the reducing agent (reducing agent supply, exposure). At that time, the valves 243f to 243h may be opened to supply the inert gas into the processing chamber 201 via the nozzles 249a to 249c, respectively.

Processing conditions in the baking treatment are exemplified as follows:
processing temperature: 700 to 1,000° C., preferably 800 to 900° C.,
processing pressure: 30 to 2,000 Pa, preferably 30 to 1,000 Pa,
processing time: 30 to 120 minutes, preferably 30 to 90 minutes,
reducing agent supply flow rate: 1 to 10 slm, preferably 1 to 5 slm, and
inert gas supply flow rate (per gas supply pipe): 0 to 20 slm, preferably 1 to 10 slm.

By supplying the reducing agent to the wafer 200 and the dummy wafer under the above-described processing conditions, it is possible to remove substances, including by-products such as organic substances and moisture remaining on the surfaces of the wafer 200 and the dummy wafer and in the processing chamber 201 after step A′ is finished by reaction with the reducing agent. That is, by this step, the surfaces of the wafer 200 and the dummy wafer and the inside of the processing chamber 201 can be brought into a cleaned state, and the cleaned state can be maintained until step C is performed. Note that, in a case where the surfaces of the wafer 200 and the dummy wafer and the inside of the processing chamber 201 can be maintained in the cleaned state after performing step B and before performing step C, the baking treatment may be omitted. FIG. 4 illustrates an example in which the baking treatment is omitted.

### (Step C)

Thereafter, the source, as the film-forming agent and the reducing agent, are supplied into the processing chamber 201 in a state in which the wafer 200 and the dummy wafer are arranged.

Specifically, the valves 243b and 243d are opened to cause the source and the reducing agent to flow into the gas supply pipes 232b and 232d, respectively. The source and the reducing agent the flow rates of which are regulated by the MFCs 241b and 241d are supplied into the processing chamber 201 through the nozzles 249b and 249a, respectively, and discharged from the exhaust port 231a. At that time, the source and the reducing agent are supplied from the lateral side of the wafer 200 and the dummy wafer to the wafer 200 and the dummy wafer, and the wafer 200 and the dummy wafer are exposed to the source and the reducing agent (source+reducing agent supply, exposure). At that time, the valves 243f to 243h may be opened to supply the inert gas into the processing chamber 201 via the nozzles 249a to 249c, respectively.

By supplying the source and the reducing agent into the processing chamber 201 in a state in which the wafer 200 and the dummy wafer are arranged under processing conditions to be described later, a predetermined film can be formed on the surface of the wafer 200 from which the oxide is removed. In a case where the surface of the wafer 200 is formed of single crystal Si, and substances to be described later are used as the source and the reducing agent, it is possible to cause an epitaxial Si film to grow as the film and form the same on the surface of the wafer 200. At that time, the surface of the wafer 200 and the inside of the processing chamber 201 can be maintained in a cleaned state by the action of the reducing agent, and epitaxial growth can be appropriately performed to form the epitaxial Si film having high purity.

After a predetermined film is formed on the surface of the wafer 200, the valves 243b and 243d are closed to stop supplying the source and the reducing agent into the processing chamber 201. By the processing procedure and processing conditions similar to those in the purge at step B, the gaseous substance and the like remaining in the processing chamber 201 are removed from the inside of the processing chamber 201 (purge). Note that the processing temperature when performing the purge at this step is preferably similar to the processing temperature when supplying the source and the reducing agent.

The processing conditions when supplying the source and reducing agent at step C are exemplified as follows:
processing temperature: 500 to 650° C., preferably 550 to 600° C.,
   processing pressure: 4 to 200 Pa, preferably 1 to 120 Pa,
   processing time: 10 to 120 minutes, preferably 20 to 60 minutes,
   source supply flow rate: 0.1 to 5 slm, preferably 0.2 to 3 slm,
   reducing agent supply flow rate: 1 to 20 slm, preferably 1 to 10 slm, and
   inert gas supply flow rate (per gas supply pipe): 0 to 20 slm, preferably 0.1 to 10 slm.

As the source, for example, silicon hydride such as monosilane (SiH₄), disilane (Si₂H₆), trisilane (Si₃H₈), and tetrasilane (Si₄H₁₀) can be used.

For example, the H-containing substance and the D-containing substance, such as H₂ and D₂, can be used as the reducing agent. One or more of them can be used as the reducing agent.

### (After-Purge and Atmospheric Pressure Restoration)

After step C is finished, the inside of the processing chamber 201 is purged, the atmosphere in the processing chamber 201 is replaced with the inert gas, and the pressure in the processing chamber 201 is restored to the normal pressure by the processing procedure similar to that of the after-purge and atmospheric pressure restoration described above.

### (Boat Unload)

Thereafter, the boat 217 that supports the processed wafer 200 and the dummy wafer is discharged by the processing procedure similar to that of the boat unload and shutter close at step A′, and the lower end opening of the manifold 209 is sealed with the shutter 219s.

### (Step D)

After the boat is unloaded, processing of eliminating adhesion of the wafer 200 to the boat 217 by the film formed at step C is performed outside the processing chamber 201. This processing can be performed by, for example, temporarily separating (picking up) the wafer 200 from the boat 217. For example, this processing can be performed by operating opposite to the charge of the wafer 200 on the boat 217 in the wafer charge. At that time, in a case where the dummy wafer is adhered to the boat 217, a similar processing is also performed on the dummy wafer. For example, by temporarily separating the dummy wafer from the boat 217 together with the wafer 200, the adhesion of the dummy wafer to the boat 217 can be eliminated.

Note that, when the boat is unloaded and step D are performed, the wafer 200, the film-forming processing of which is finished, might be exposed to the atmosphere in some cases. At that time, when the temperature of the wafer 200 is relatively high (500 to 650° C.), the H terminal is removed from the surface of the wafer 200, a dangling bond is generated on the surface of the wafer 200, and the surface of the wafer 200 might be easily oxidized in some cases. When the wafer 200 is exposed to the atmosphere in this state, oxygen in the atmosphere is bonded to the dangling bond generated on the surface of the wafer 200, and the surface of the wafer 200 might be oxidized in some cases. However, the oxide generated at this timing can be etched and removed at step B in the next cycle.

### [Perform Predetermined Number of Times]

By performing a cycle including the above-described steps A to D a predetermined number of times (n times, n is 1 or an integer not smaller than 2), a film of a desired thickness can be formed on the wafer 200. This cycle is preferably performed a plurality of times. That is, as illustrated in FIG. 6, it is preferable that the thickness of the film (the thickness of each of first and second films) formed by performing the cycle including steps A to D once is made thinner than a desired film thickness, and the above-described cycle is repeated a plurality of times until the thickness of the film stacked on the wafer becomes a predetermined thickness. FIG. 6 illustrates an example in which this cycle is performed twice. The first film in FIG. 6 indicates the film formed in a first cycle, the second film indicates the film formed in a second cycle, and a broken line indicates a site of the surface after the oxide is removed by performing the etching at step B in each cycle. Note that a broken line between the wafer and the first film indicates a site of the surface after the oxide formed on the surface of the wafer is removed by the etching at step B in the first cycle. A broken line between the first film and the second film indicates a site of the surface after the oxide formed on the surface of the first film by taking out the wafer to the outside of the processing chamber 201 at step D in the first cycle is removed by the etching at step B in the second cycle.

Here, in a case where the cycle including steps A to D is performed a plurality of times, a used dummy wafer and a new non-product wafer to which the substance M is adsorbed are exchanged each time the cycle is performed. That is, after step D in the m-th cycle (m is an integer not smaller than 1) is performed, the used dummy wafer is taken out from the boat 217 (wafer discharge), and the new non-product wafer to which the substance M is adsorbed is charged (wafer charge) at a site where the dummy wafer is removed in the boat 217 in the wafer charge at step A in the (m+1)-th cycle, that is, the lacking site.

Note that, in a case where the cycle including steps A to D is performed a plurality of times, it is preferable to perform step E of preparing the non-product wafer to which the substance M is adsorbed outside the processing chamber 201 in parallel with execution of this cycle. That is, it is preferable to perform at least any one of steps A, B, C, and D in the m-th cycle (m is an integer not smaller than 1) and step E in the (m+1)-th cycle in parallel.

### (Wafer Discharge)

After the film of a desired thickness is formed on the wafer 200, the processed wafer 200 and the dummy wafer are taken out from the boat 217 (wafer discharge).

As above, the processing step according to one embodiment of the present disclosure is finished.

### (3) Effects by Present Embodiment

According to the present embodiment, one or a plurality of effects described below can be obtained.

(a) At step B, when the surface of the product substrate is etched, the etching agent and the substance M adsorbed to the non-product substrate are used. As a result, the etching agent and a slight amount of substance M can be caused to react with each other, and the etching reaction can be promoted. As a result, the etching can be efficiently performed. Uniformity of the etching can be improved.

The processing temperature in the etching can be raised, and in a case where another processing, such as film forming processing, is performed at least either before or after the etching processing, the processing temperature in the etching can be brought close to the processing temperature in another processing. As a result, it is possible to shorten the time required to change the processing temperature between etching processing and another processing, that is, at least one of the heat-up time or the cool-down time, and it is also possible to enhance productivity accordingly.

It is not necessary to separately provide a supply line for supplying the substance M into the processing chamber, and an apparatus cost can be reduced accordingly. Since the supply line for supplying the substance M can be omitted, the supply system can be simplified, and the time and cost for maintenance of the supply system can be reduced. By causing the substance M to adsorb to the non-product substrate and supplying the substance M into the processing chamber without providing a supply line for supplying the substance M, it is possible to precisely control the supply of a slight amount of the substance M.

(b) The oxide on the surface of the product substrate is etched at step B. This makes it possible to effectively obtain the above-described action. In a case where the oxide includes the silicon oxide film having the non-stoichiometric composition, the above-described action can be effectively obtained. In a case where the oxide comprises at least one of the native oxide film or the chemical oxide film, the above-described action can be effectively obtained.

(c) The etching agent includes the F-containing substance, and the substance M includes the oxygen and hydrogen-containing substance. This makes it possible to effectively obtain the above-described action.

(d) Step B is performed in a state in which the non-product substrate to which the substance M is adsorbed is arranged every other product substrate or every plural product substrates in the processing chamber. As a result, the substance M can be arranged (supplied) between the product substrates, that is, can be present around the product substrate, and the above-described action can be effectively obtained. By performing step B in a state in which the product substrate and the non-product substrate to which the substance M is adsorbed are arranged in the processing chamber, and making the number of the non-product substrates to which the substance M is adsorbed equal to or smaller than the number of the product substrates, or smaller than the number of the product substrates, the above-described action can be effectively obtained. By performing step B in a state in which a plurality of product substrates and a plurality of non-product substrates to which the substance M is adsorbed are arranged in the processing chamber, the above-described action can be effectively obtained.

(e) At steps A and B, the non-product substrate to which the substance M is adsorbed can be supported by a support that supports the product substrate like that of the product substrate. As a result, it is not necessary to separately provide a member for arranging the non-product substrate to which the substance M is adsorbed in the processing chamber. Similarly to the product substrate, the non-product substrate to which the substance M is adsorbed can be transferred to the support using the same transferer. That is, it is not necessary to separately provide a transferer for transferring the non-product substrate to which the substance M is adsorbed.

(f) At step C, the film-forming agent is supplied to the product substrate, the surface of which is etched to form a film on the product substrate. This makes it possible to reduce an impurity concentration (oxygen concentration and the like) at an interface between the product substrate and the film. By performing the cycle including steps A to C a predetermined number of times, for example, a plurality of times, the impurity concentration (oxygen concentration and the like) at the interface between the product substrate and the film can be reduced, and the impurity concentration (oxygen concentration and the like) at the interface between the film formed in the m-th cycle and the film formed in the (m+1)-th cycle can be reduced.

(g) Step C is performed in the processing chamber in a state in which the non-product substrate to which the substance M is adsorbed is removed. That is, after performing step B and before performing step C, step A′ is performed in which the support is carried out of the processing chamber, the non-product substrate to which the substance M is adsorbed is removed from the support outside the processing chamber, and then the support in a state of supporting the product substrate is carried into the processing chamber. This makes it possible to form the film without the reaction of the film-forming agent with the substance M adsorbed to the non-product substrate. As a result, it is possible to cause the film to grow appropriately while suppressing film-formation defects, and it is possible to form a film having high purity.

(h) Step B is performed in a state in which the product substrate and the non-product substrate to which the substance M is adsorbed are supported by the support in the processing chamber, and step C is performed in a state in which the product substrate is supported by the support in the processing chamber. That is, the product substrate is similarly supported at steps A and B and step C. As a result, it is not necessary to newly charge the product substrate for each step, and the productivity can be increased accordingly.

(i) At step A′, the dummy substrate is charged at a site where the non-product substrate to which the substance M is adsorbed is removed in the support, and the support that supports the product substrate and the dummy substrate is carried into the processing chamber. That is, the site where the non-product substrate to which the substance M is adsorbed is removed from the support is not brought into the lacking site. As a result, the distance between the product substrates, that is, the size of a space between the product substrates can be made uniform, and the flow of the film-forming agent to the product substrates can be made uniform at step C. As a result, it is possible to improve the uniformity of the film thickness between the product substrates.

(j) After step C is performed, the support is carried out of the processing chamber, and the product substrate is separated from the support outside the processing chamber. This makes it possible to eliminate adhesion of the product substrate to the support by the film.

(k) At step E, the non-product substrate to which the substance M is adsorbed is prepared outside the processing chamber. For example, at step E, the non-product substrate is exposed to the atmosphere to prepare the non-product substrate to which the substance M is adsorbed. In this case, the substance M includes moisture (H₂O) in the atmosphere. In this manner, at step E, it is not necessary to prepare the product substrate on a front surface, a rear surface and the like of which a special film or mechanism containing moisture is formed, and an increase in cost can be avoided.

(1) That is, step E of preparing the non-product substrate to which the substance M is adsorbed outside the processing chamber is performed, and at least any one of steps A, B, C, and D in the m-th cycle (m is an integer not smaller than 1) and the step E in the (m+1)-th cycle are performed in parallel. As a result, it is possible to prevent the cycle time, that is, the processing time from becoming longer, and it is possible to avoid the reduction in productivity.

(m) By making the shape and size of the non-product substrate similar to the shape and size of the product substrate, the non-product substrate and the product substrate can be handled similarly. For example, transferring the substrate between the FOUP and the support, charging the substrate on the support, supporting the substrate on the support, storing the substrate by the FOUP, and the like, can be performed similarly between the non-product substrate and the product substrate. This makes it possible to avoid an increase in cost and a reduction in productivity.

(n) The above-described effects can be similarly obtained even in a case where a predetermined substance is optionally selected from the various etching agents, various film-forming agents, various reducing agents, and various inert gases described above to be used.

### Other Embodiments of Present Disclosure

The embodiments of the present disclosure have been specifically described above. However, the present disclosure is not limited to the above-described embodiments, and various modifications can be made without departing from the gist thereof.

For example, at step A′ of the above-described embodiments, after the non-product substrate to which the substance M is adsorbed is removed from the support outside the processing chamber, the support that supports only the product substrate may be carried into the processing chamber without charging the dummy substrate at the site where the non-product substrate is removed. That is, step C may be performed in the processing chamber in a state in which only the product substrate is supported by the support without supporting the dummy substrate by the support. Even in this case, effects similar to those in the above-described embodiments can be obtained.

For example, in the cycle of the above-described embodiments, it is possible that step D is not performed, and the cycle including steps A, B, and C is performed a predetermined number of times (n times, n is 1 or an integer not smaller than 2). Even in this case, effects similar to those in the above-described embodiments can be obtained. Note that, in a case where step D is not performed and the cycle including steps A, B, and C a plurality of times, it is preferable to perform step E of preparing the non-product substrate to which the substance M is adsorbed outside the processing chamber, and perform at least any one of steps A, B, and C in the m-th cycle and step E in the (m+1)-th cycle in parallel. As a result, it is possible to prevent the cycle time, that is, the processing time from becoming longer, and it is possible to avoid the reduction in productivity as in the above-described embodiments.

For example, at step B of the above-described embodiments, the etching agent may be intermittently, that is, in a pulse manner, supplied into the processing chamber. For example, the supply of the etching agent into the processing chamber and the purge in the processing chamber and/or the vacuum-exhaust in the processing chamber may be alternately performed a predetermined number of times (x times, x is 1 or an integer not smaller than 2). Even in this case, effects similar to those in the above-described embodiments can be obtained. According to the present embodiments, by once removing the reaction product and a residual gas from the inside of the processing chamber in the middle of etching and resetting the reaction, it is possible to suppress the occurrence of an excessive etching reaction and to enhance the controllability of the etching amount.

For example, at step C of the above-described embodiments, the dopant may be supplied to the product substrate as the film-forming agent in addition to the source and the reducing agent. The dopant can be provided from the dopant supply system described above. As the dopant, a substance containing any element of group 15 elements, such as phosphorus (P) and arsenic (As), and group 13 elements, such as boron (B), can be used. As the dopant, for example, phosphine arsine (PH₃), (AsH₃), diborane (B₂H₆), trichloroborane (BCl₃) and the like can be used. One or more of them can be used as the dopant. In the present embodiment, effects similar to those in the embodiments described above can be obtained. According to the present embodiment, a film doped with a dopant (P, As, B, and the like) can be formed on the product substrate.

For example, at step C of the above-described embodiments, a semiconductor element-containing film other than the Si-containing film may be formed on the product substrate using a substance containing a semiconductor element other than Si. For example, a substance containing germanium (Ge) such as monogermane (GeH₄), may be used as the source, and a Ge-containing film, such as a Ge film, may be formed on the product substrate. For example, a Si-containing substance and a Ge-containing substance may be used as the source, and a Si- and Ge-containing film, such as a SiGe film, may be formed on the product substrate. For example, a Si-based insulating film such as a silicon oxide film (SiO film), a silicon nitride film (SiN film), or a silicon oxynitride film (SiON film) may be formed on the product substrate using an oxidizing agent or a nitriding agent in addition to the Si-containing substance. For example, by using a substance containing a metal element such as tungsten (W), molybdenum (Mo), aluminum (Al), titanium (Ti), zirconium (Zr), hafnium (Hf), and tantalum (Ta) as the source, a metal element-containing film may be formed on the product substrate. For example, by using the metal element-containing substance and the Si-containing substance as the source, a metal element and Si-containing film, such as a metal silicide film, may be formed on the product substrate. For example, by using the oxidizing agent in addition to the metal element-containing substance and the Si-containing substance, a metal element-, Si-, and oxygen-containing film, such as a metal silicate film may be formed on the product substrate. Even in these cases, effects similar to those in the above-described embodiments can be obtained. Note that, in a case where two or more kinds of sources are used, such as in a case where the Si-containing substance and the Ge-containing substance are used, or in a case where the metal element-containing substance and the Si-containing substance are used, these substances can be supplied simultaneously or non-simultaneously using the source supply system and another source supply system.

For example, at step C of the above-described embodiments, in addition to an epitaxial film, an amorphous film (amorphous film), a polycrystalline film (poly film), or a mixed crystal film thereof may be formed on the product substrate. For example, in addition to the epitaxial Si film, an amorphous Si film, a poly-Si film, or a mixed crystal Si film of amorphous and poly may be formed on the product substrate. Even in these cases, effects similar to those in the above-described embodiments can be obtained.

Preferably, a recipe used in each processing is individually prepared according to processing contents and is recorded and stored in the memory 121c via an electric communication line or the external memory 123. When each processing is started, the CPU 121a preferably appropriately selects an appropriate recipe from among a plurality of recipes recorded and stored in the memory 121c according to the processing contents. Therefore, it is possible to perform the various pieces of processing on films with various film types, composition ratios, film qualities, and film thicknesses with excellent reproducibility by using the processing apparatus. It is possible to reduce the burden on an operator, and to quickly start each processing while avoiding an operation error.

The recipe described above is not limited to a newly created recipe, but may be prepared by, for example, changing the existing recipe already installed in the processing apparatus. In a case of changing the recipe, the changed recipe may be installed in the processing apparatus via an electric communication line or a recording medium in which the recipe is recorded. The existing recipe already installed in the processing apparatus may be directly changed by operating the input/output 122 included in the existing processing apparatus.

In the embodiments described above, an example has been provided in which processing is performed using a batch-type processing apparatus that processes a plurality of substrates simultaneously. The present disclosure is not limited to the embodiments described above, and can be applied to a case of performing the processing by using a single wafer type processing apparatus that processes one or a plurality of substrates at a time, for example. In the embodiments described above, an example of performing the processing using the processing apparatus, including a hot wall type processing furnace, has been described. The present disclosure is not limited to the embodiments described above, and can be applied to a case of performing the processing by using the processing apparatus, including a cold wall type processing furnace.

In the embodiments described above, an example has been described in which the above-described processing sequence is performed in the same processing chamber of the same processing apparatus (in-situ). The present disclosure is not limited to the embodiments described above, and for example, any step and any other step of the above-described processing sequence may be performed in different processing chambers of different processing apparatuses (ex-situ), or may be performed in different processing chambers of the same processing apparatus.

Even in a case where such processing apparatuses are used, each processing can be performed in accordance with processing procedures and processing conditions similar to those in the embodiments described above and variations, so that effects similar to those in the embodiments described above and variations can be obtained.

The embodiments described above and variations can be used in combination as appropriate. The processing procedures and processing conditions at that time can be similar to the processing procedures and processing conditions in the embodiments described above and variations, for example.

### EXAMPLE

As an example, a Si wafer, on a surface of which a native oxide film was formed and a Si wafer (hereinafter, a moisture-adsorbed wafer) on a surface of which moisture in the atmosphere was adsorbed, were arranged in a processing chamber, and a HF gas was supplied into the processing chamber to etch the surface of the Si wafer. At that time, the etching amount was measured in a case where the processing temperature when supplying the HF gas was set to 50, 75, 100, 150, and 200° C. Other processing conditions when supplying the HF gas were predetermined conditions within a processing condition range at step B in the above-described embodiments.

As a comparative example, only a Si wafer, on a surface of which a native oxide film was formed, was arranged without arranging a moisture-adsorbed wafer in the processing chamber, and a HF gas was supplied into the processing chamber to etch the surface of the Si wafer. At that time, the etching amount was measured in a case where the processing temperature when supplying the HF gas was set to 50, 75, and 100° C. Other processing conditions when supplying the HF gas were similar to the processing conditions in the example.

FIG. 7 illustrates a measurement result of the etching amount of the native oxide film on the surface of the Si wafer. In FIG. 7, the horizontal axis represents the processing temperature [C] when supplying the HF gas, and the vertical axis represents the etching amount [a.u.] of the native oxide film. A solid line in FIG. 7 indicates the measurement result of the etching amount of the native oxide film in the example, and a broken line indicates the measurement result of the etching amount of the native oxide film in the comparative example. In FIG. 7, ∘ and □ indicate measurement results in the wafers arranged in a lower portion and an upper portion in the processing chamber, respectively, in this order. As illustrated in FIG. 7, it is understood that the etching amount of the native oxide film in the example does not decrease at all in a range of the processing temperature of 130° C. or lower, a decrease amount is very small even in a range higher than 130° C. and 150° C. or lower, and a sufficiently practical etching amount can be obtained even in the range higher than 150° C. and 170° C. or lower. In contrast, it is understood that the etching amount of the native oxide film in the comparative example remarkably decreases in the temperature range of 75° C. or higher. That is, according to the example, it is understood that the etching of the native oxide film on the surface of the Si wafer can be efficiently performed at relatively high temperature, and the productivity can be significantly improved.

According to the present disclosure, etching of a surface of a substrate can be efficiently performed.

What is claimed is:

1. A processing method comprising:
(a) establishing a state in which a product substrate and a non-product substrate to which a substance M is adsorbed are placed in a processing chamber; and
(b) etching a surface of the product substrate by supplying an etching agent into the processing chamber in the state in which the product substrate and the non-product substrate are placed to cause the substance M adsorbed to the non-product substrate to react with the etching agent.

2. The processing method according to claim 1, wherein an oxide on the surface of the product substrate is etched in (b).

3. The processing method according to claim 2, wherein
the oxide includes a silicon oxide film having a non-stoichiometric composition.

4. The processing method according to claim 2, wherein
the oxide includes at least one selected from the group of a native oxide film and a chemical oxide film.

5. The processing method according to claim 1, wherein
the etching agent includes a fluorine-containing substance, and the substance M includes an oxygen- and hydrogen-containing substance.

6. The processing method according to claim 1, wherein
(b) is performed in a state in which the non-product substrate is arranged every other product substrate or every plural product substrates in the processing chamber.

7. The processing method according to claim 1, wherein
(b) is performed in a state in which the product substrate and the non-product substrate are arranged in the processing chamber, and the number of non-product substrates is made equal to or smaller than the number of product substrates or smaller than the number of product substrates.

8. The processing method according to claim 1, wherein
(b) is performed in a state in which a plurality of product substrates and a plurality of non-product substrates are arranged in the processing chamber.

9. The processing method according to claim 1, wherein
(b) is performed in a state in which the product substrate and the non-product substrate are supported by a support in the processing chamber.

10. The processing method according to claim 1, further comprising:
(c) forming a film on the product substrate by supplying a film-forming agent to the product substrate, the surface of which is etched, the method performing
a cycle including (a), (b), and (c) a predetermined number of times.

11. The processing method according to claim 10, wherein
(c) is performed in the processing chamber in a state in which the non-product substrate is removed.

12. The processing method according to claim 10, wherein
(b) is performed in a state in which the product substrate and the non-product substrate are supported by a support in the processing chamber, and (c) is performed in a state in which the product substrate is supported by the support in the processing chamber.

13. The processing method according to claim 12, wherein
the cycle further includes:
(a′) carrying the support out of the processing chamber, and after removing the non-product substrate from the support outside the processing chamber, carrying the support in a state of supporting the product substrate into the processing chamber, after performing (b) and before performing (c).

14. The processing method according to claim 13, wherein
in (a′), a dummy substrate is charged at a site where the non-product substrate is removed in the support, and the support that supports the product substrate and the dummy substrate is carried into the processing chamber.

15. The processing method according to claim 12, wherein
the cycle further includes:
(d) eliminating adhesion of the product substrate to the support by the film by carrying the support out of the processing chamber and separating the product substrate from the support outside the processing chamber after performing (c).

16. The processing method according to claim 1, further comprising:
(e) preparing the non-product substrate to which the substance M is adsorbed outside the processing chamber.

17. The processing method according to claim 16, wherein the substance M includes moisture in an atmosphere.

18. The processing method according to claim 10, wherein the cycle further includes:
(e) preparing the non-product substrate to which the substance M is adsorbed outside the processing chamber, and
at least one selected from the group of (a), (b), and (c) in an m-th cycle (m is an integer not smaller than 1) and (e) in an (m+1)-th cycle are performed in parallel.

19. The processing method according to claim 15, wherein the cycle further includes:
(e) preparing the non-product substrate to which the substance M is adsorbed outside the processing chamber, and
at least one selected from the group of (a), (b), (c), and (d) in an m-th cycle (m is an integer not smaller than 1) and (e) in an (m+1)-th cycle are performed in parallel.

20. A method of manufacturing a semiconductor device, comprising:
the method according to claim 1.

21. A processing apparatus comprising:
a processing chamber;
an apparatus that establishes a state in which a product substrate and a non-product substrate to which a substance M is adsorbed are placed in the processing chamber;
an etching agent supply system that supplies an etching agent into the processing chamber; and
a controller configured to be capable of controlling the apparatus and the etching agent supply system so as to perform:
(a) establishing the state in which the product substrate and the non-product substrate are placed in the processing chamber, and
(b) etching a surface of the product substrate by supplying the etching agent into the processing chamber in the state in which the product substrate and the non-product substrate are placed to cause the substance M adsorbed to the non-product substrate to react with the etching agent.

22. A non-transitory computer-readable recording medium storing a program that causes, by a computer, a processing apparatus to execute:
(a) establishing a state in which a product substrate and a non-product substrate to which a substance M is adsorbed are placed in a processing chamber; and
(b) etching a surface of the product substrate by supplying an etching agent into the processing chamber in the state in which the product substrate and the non-product substrate are placed to cause the substance M adsorbed to the non-product substrate to react with the etching agent.
